(19) United States
(12) Patent Application Publication
(10) Pub. No.: US 2019/0157479 A1
(43) Pub. Date: May 23, 2019

(54) PHOTODETECTION ELEMENT, PHOTODETECTOR, PHOTODETECTION SYSTEM AND LASER IMAGING DETECTION AND RANGING APPARATUS

(71) Applicant: Kabushiki Kaisha Toshiba, Minato-ku (JP)

(72) Inventors: Yuki Nobusa, Yokohama Kanagawa (JP); Kazuhiro Suzuki, Meguro Tokyo (JP)

(73) Assignee: Kabushiki Kaisha Toshiba, Minato-ku (JP)

(21) Appl. No.: 16/211,836

(22) Filed: Dec. 6, 2018

Related U.S. Application Data
(63) Continuation-in-part of application No. 15/909,686, filed on Mar. 1, 2018, now abandoned.

(30) Foreign Application Priority Data
Sep. 15, 2017 (JP) 2017-178191
Sep. 13, 2018 (JP) 2018-171668

(51) Int. Cl. H01L 31/0352; H01L 27/144; H01L 31/02; H01L 31/107; G01S 7/481

(52) U.S. Cl. CPC H01L 31/03529; H01L 27/1443; G01S 7/4816; H01L 31/107; H01L 31/02027

(57) ABSTRACT

A photodetection element includes a first semiconductor layer; and a second semiconductor layer stacked on the first layer and converting light into electric charges; wherein the first semiconductor layer has a thickness of 5 μm or less.

### CROSS-REFERENCE TO RELATED APPLICATIONS

This application is based upon and claims the benefit of priority from the prior Japanese Patent Application No. 2017-178191, filed on Sep. 15, 2017 and the prior Japanese Patent Application No. 2018-178191, filed on Sep. 13, 2018, the entire contents of which are incorporated herein by reference. This application is also a continuation in part application of the U.S. patent application U.S. Ser. No. 15/909,686, the entire contents of which are incorporated herein by reference.

### FIELD

Embodiments described herein relate generally to a photodetection element, a photodetector, a photodetection system and a laser imaging detection and ranging apparatus.

### BACKGROUND

A photodetection efficiency of a photodetection element is increased by applying a large voltage. However, generally, a dark current which is a cause of noise is also increased, and the performance as the photodetection element is deteriorated. Therefore, there is a tradeoff between the noise reduction and the increased photodetection efficiency. Therefore, even when a large voltage is applied, a photodetection element with less noise is required.

### SUMMARY

The invention is to provide a photodetection element with less noise even when a large voltage is applied.

In order to achieve the above object, a photodetection element according to an embodiment includes a first semiconductor layer and a second semiconductor layer that is provided on the first semiconductor layer and converts light into electric charges, wherein the first semiconductor layer has a thickness of 5 μm or less.

### BRIEF DESCRIPTION OF THE DRAWINGS

FIG. 1 is a diagram illustrating a photodetector according to a first embodiment;

FIG. 2 is a diagram illustrating a p-p′ cross section of a photodetection element of the photodetector illustrated in FIG. 1;

FIG. 3 is a graph illustrating voltage characteristics of a dark current in a photodetection element;

FIG. 4 is a diagram illustrating an example of a mechanism by which a photocurrent flows in the photodetection element of FIG. 2;

FIG. 5 is a graph illustrating a relationship between a thickness of a first semiconductor layer of the photodetection element and a voltage V_{c} applied to the photodetection element illustrated in FIG. 2;

FIG. 6 is a graph illustrating a relationship between a thickness and a yield of the first semiconductor layer of the photodetection element illustrated in FIG. 2;

FIG. 7 is a diagram illustrating a modified example of the photodetector according to the first embodiment;

FIG. 8 is a diagram illustrating a LIDAR apparatus according to a second embodiment;

FIG. 9 is a diagram illustrating detection of the LIDAR apparatus according to this embodiment; and

FIG. 10 is a schematic top view of a vehicle equipped with the LIDAR apparatus according to this embodiment.

### DETAILED DESCRIPTION OF THE PREFERRED EMBODIMENTS

Hereinafter, embodiments of the invention will be described with reference to the drawings. Components denoted by the same reference numerals indicate corresponding ones. The drawings are schematic or conceptual, and a relationship between thickness and width of each portion, a ratio of sizes among portions, and the like are not necessarily the same as actual ones. In addition, even in the case of representing the same portions, the sizes and ratios of the portions may be different from each other depending on figures in the drawings.

### First Embodiment

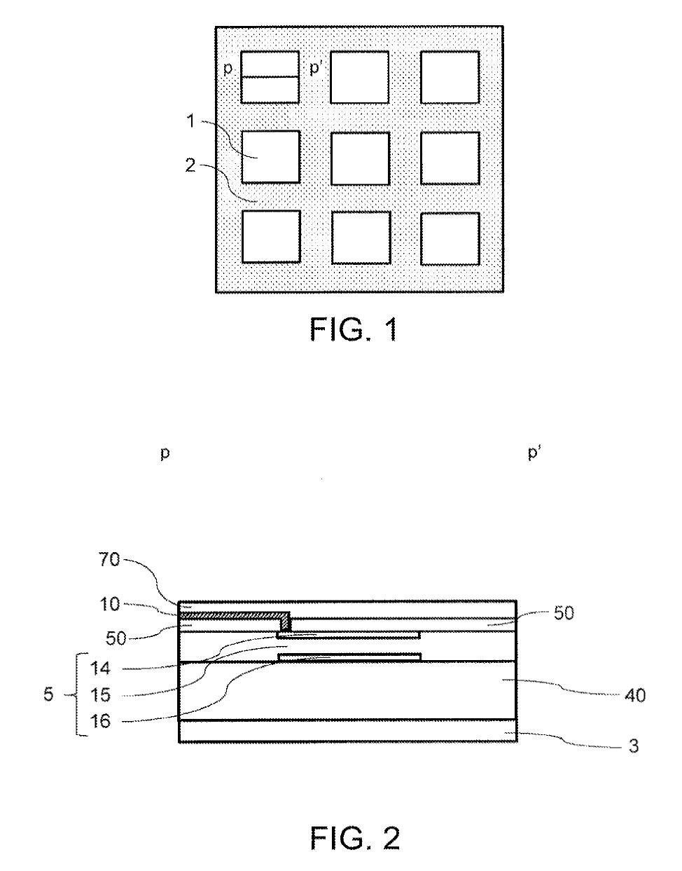

FIG. 1 is a diagram illustrating a photodetector according to a first embodiment. This photodetector can convert incident light into electric charges and detect the light as an electric signal.

In FIG. 1, the photodetector includes a plurality of photodetection elements 1 arranged in an array shape and a non-photodetection area 2 provided between a plurality of the photodetection elements 1. Herein, the “upper” denotes the side on which light is incident.

The non-photodetection area 2 is an area in which incident light cannot be detected. The non-photodetection area 2 is an area for preventing adjacent photodetection elements 1 from interfering with each other and is an area in which wiring is provided for transmitting electric signals converted by the photodetection elements 1 to a driving/reading unit (not illustrated).

The photodetection element 1 detects light by converting incident light into electric charges. For example, the photodetection element is an avalanche photodiode which operates in the Geiger mode.

FIG. 2 is a diagram illustrating a p-p′ cross section of a photodetection element 1 of the photodetector illustrated in FIG. 1.

The photodetection element 1 includes a first electrode 3, an n-type semiconductor layer 40 (sometimes, referred to as a first semiconductor layer), a p-type semiconductor layer 5 (sometimes, referred to as a second semiconductor layer), an insulating layer 50, a second electrode 10, and a protective layer 70 protecting the second electrode 10.

In the p-p′ cross section of FIG. 2, the n-type semiconductor layer 40 is stacked on the first electrode 3, and the p-type semiconductor layer 5 is stacked on the n-type semiconductor layer 40. The p-type semiconductor layer 5 includes a p− layer 15, a p+ layer 16 provided at least partially in the vicinity of the lower surface of the p− layer 15, and a p+ layer 14 provided at least partially in the vicinity of the upper surface of the p− layer 15. The insulating layer 50 is provided on the p-type semiconductor layer 5. The second electrode 10 is electrically connected to the p+ layer 14 in a portion of the insulating layer 50. In addition, the second electrode 10 is electrically connected to a wiring (not illustrated) of the non-photodetection area 2 on the upper surface of the insulating layer 50.

The protective layer 70 is provided so as to cover the upper surface of the insulating layer 50 and the upper surface of the second electrode 10.

The surface of the p+ layer 14 is a light-receiving surface. The second electrode 10 is provided between the insulating layer 50 and the protective layer 70. However, the p-p′ cross section is a cross section taken along a plane including the stacking direction and the plane direction.

The first electrode 3 is provided to apply a voltage to cause a potential difference to occur between the first electrode and the second electrode 10 (p+ layer 14). The material of the first electrode 3 is, for example, aluminum, an aluminum-containing material, or other metal materials combined with the material.

The n-type semiconductor layer 40 is preferably formed by doping a high-purity semiconductor (for example, silicon) with impurities (for example, phosphorus) at a high concentration of 1×10¹⁶/cm³ or more. As the concentration of the n-type semiconductor layer 40 becomes higher, the electric charge transfer is suppressed, and thus, the electric charges formed by the secondary photons can be more easily removed.

The p⁻-type semiconductor layer 15 is formed by doping a high-purity semiconductor (for example, silicon) with impurities (for example, boron) at a concentration of 1×10¹⁵/cm³. The thickness of the p⁻-type semiconductor layer 15 is preferably 2 μm or more and 4 μm or less. The thickness according to this embodiment can be measured by a laser displacement meter. In addition, the thickness according to this embodiment is an average thickness, which is the average of the maximum thickness and the minimum thickness when the thickness is measured a plurality of times with the laser displacement meter described above.

The second electrode 10 is provided to transmit the photoelectrically converted electric charges to the non-photodetection area 2. The material of the second electrode 10 is, for example, aluminum, an aluminum-containing material, or other metal materials combined with the material.

The insulating layer 50 is provided so that the second electrode 10 is not short-circuited with the peripheral wiring and the p− layer 15. The material of the insulating layer 50 is, for example, a silicon oxide film or a silicon nitride film.

The protective layer 70 is provided to protect the second electrode 10 so as not to be short-circuited due to contact with the outside. The material of the protective layer 70 is, for example, a silicon oxide film or a silicon nitride film.

Next, a relationship between an applied voltage and a dark current between the first electrode 3 and the second electrode 10 will be described.

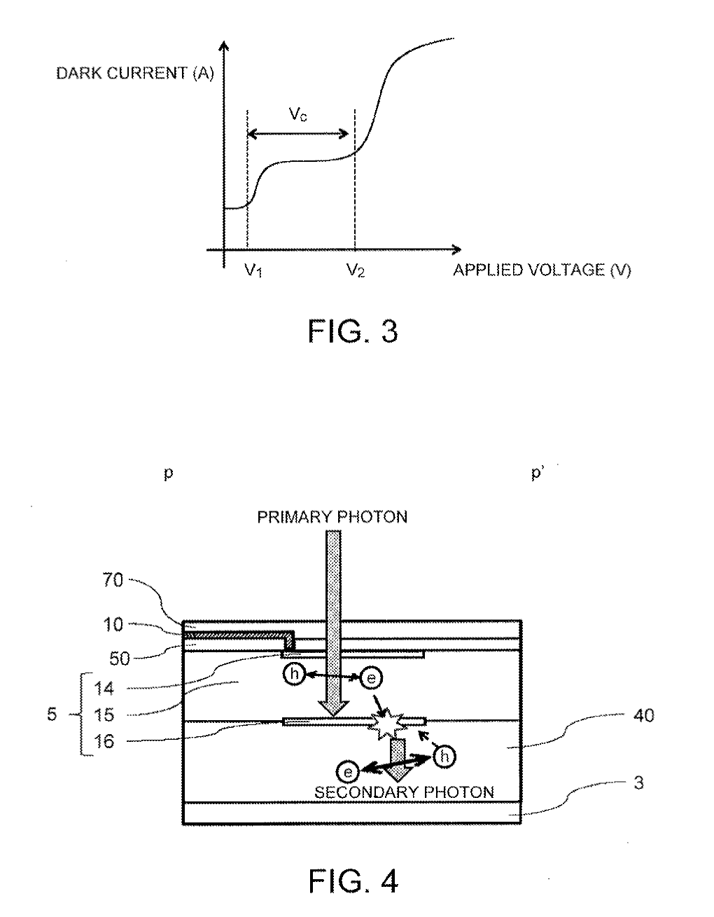

FIG. 3 is a conceptual diagram illustrating voltage characteristics of the dark current in the photodetection element 1.

As illustrated in FIG. 3, in the rough shape of the graph, the dark current rapidly increases at the voltage V₁, and when the voltage is applied as it is, the dark current further increases at the voltage V₂. The voltage V₁ is the minimum value of the voltage required to multiply the signal in the photodetection element 1, and a voltage larger than the voltage V₂ is not suitable for the driving voltage because noise becomes dominant. It is effective to apply a larger voltage to the photodetection element 1 in terms of high photodetection efficiency. When the range between the voltage V₁ and the voltage V₂ is defined as V_{c} and the voltage V₁ is set to be constant, the voltage range V_{c} increases as the voltage V₂ increases. Therefore, as the voltage range V_{c} increases, the applied voltage can also be increased, so that the photodetection element with high photodetection efficiency and less noise can be realized.

The effect of reducing the thickness of the n-type semiconductor layer 40 in photodetection element will be described.

FIG. 4 is a diagram illustrating an example of s mechanism by which a photocurrent flows in the photodetection element 1 of FIG. 2.

As illustrated in FIG. 4, light (hereinafter, referred to as primary photons) having an appropriate wavelength is incident on the light-receiving surface. Holes (h) and electrons (e) are formed from the incident primary photons by the p-type semiconductor layer 5. The holes (h) and the electrons (e) are collectively called carriers. The electrons (e) formed by the p-type semiconductor layer 5 move to the vicinity of the pn junction, and the number of electrons increases due to the avalanche effect. While avalanche amplification is occurring, the secondary photons are emitted by processes such as recombination, and then, the secondary photons are incident on the n-type semiconductor layer 40 in FIG. 4. Holes (h) and electrons (e) are formed from the secondary photons by the n-type semiconductor layer 40. In the example of FIG. 4, the holes (h) reach the vicinity of the pn junction to generate the secondary photons due to the avalanche effect, which causes noise. Therefore, by reducing the thickness of the n-type semiconductor layer 40, which is the noise generation place, the formation of carriers by the secondary photons can be reduced.

Next, a relationship between the thickness of the n-type semiconductor layer 40 and the voltage range V_{c} applied between the first electrode 3 and the second electrode 10 will be described.

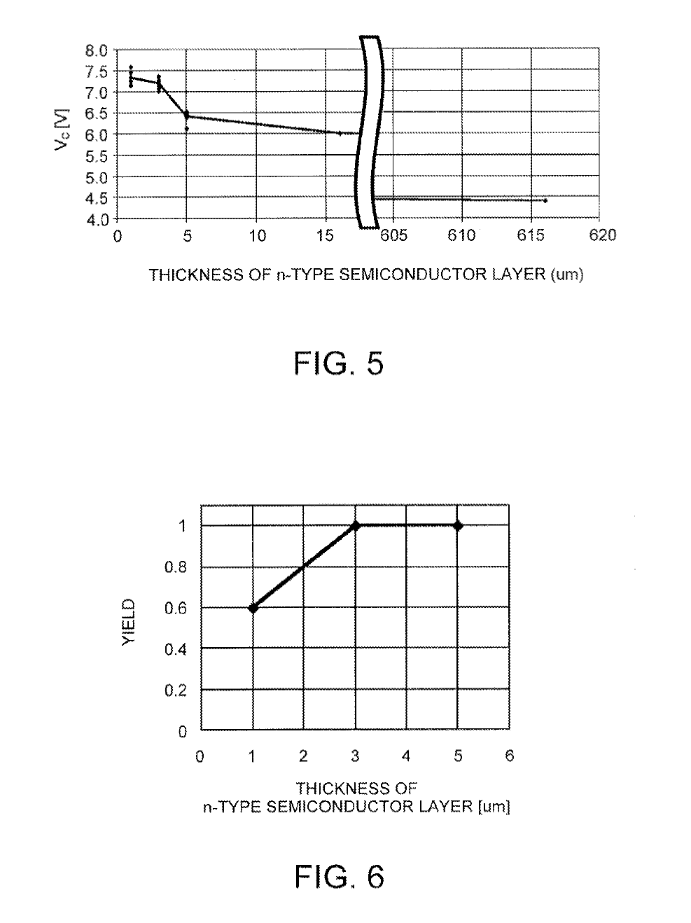

FIG. 5 is a diagram illustrating the relationship between the thickness of the first semiconductor layer of the photodetection element illustrated in FIG. 2 and the voltage range V_{c} applied to the photodetection element.

As illustrated in FIG. 5, when the thickness of the n-type semiconductor layer 40 is reduced from 616 μm to 5 μm, the voltage range V_{c} is gradually increased. In addition, when the thickness of the n-type semiconductor layer 40 is reduced from 5 μm to 1 μm, the amount of increase in the voltage range V_{c} rapidly increases as compared with the amount of increase from 616 μm to 5 μm, and thus, when the thickness is 1 μm, the largest voltage range V_{c} can be obtained.

In a case where the thickness of the n-type semiconductor layer 40 is between 616 μm and 5 μm, since the n-type semiconductor layer 40 is thick, many carriers are formed by the secondary photons. In the meantime, the distance at which the carriers formed by the n-type semiconductor layer 40 reaches the pn junction is constant. Even if many carriers are formed, a large portion of the carriers generated in a portion deeper than 5 μm from the vicinity of the pn junction in the n-type semiconductor layer 40 disappears before the carriers reach the vicinity of the pn junction. Therefore, the amount of increase in the voltage range V_{c} becomes small by reducing the thickness of the n-type semiconductor layer 40 to a range of from 616 μm to 5 μm. On the other hand, when the thickness of the n-type semiconductor layer 40 is set to be between 5 μm and 1 μm, the thickness of the n-type semiconductor layer 40 is reduced, and then, the carriers formed in the n-type semiconductor layer 40 almost reach the pn junction. However, since the thickness of the n-type semiconductor layer 40 is smaller than the above-described constant distance, the amount of the carriers due to the secondary photons is reduced in the n-type semiconductor layer 40. Therefore, the thinner the n-type semiconductor layer 40, the larger the voltage range V_{c}.

Next, the yield when the photodetector is manufactured with the thickness of the n-type semiconductor layer 40 at 1, 3, and 5 μm will be described.

FIG. 6 is a graph illustrating the relationship between the thickness of the first semiconductor layer and the yield of the photodetection element illustrated in FIG. 2.

As illustrated in FIG. 6, when the thickness of the n-type semiconductor layer 40 was 3 and 5 μm, the yield was high. However, when the thickness was 1 μm, the yield was relatively low. Herein, the yield represents the proportion of samples with normal IV characteristics taken in the mounting evaluation. When the thickness of the n-type semiconductor layer 40 is 1 μm, the yield is low because it is considered that the sample is so thin to be damaged in the stage of thinning or during the mounting.

In terms of the yield, the thickness of the n-type semiconductor layer 40 is preferably 3 μm or more.

From the above results, the thickness of the n-type semiconductor layer 40 is more preferably 3 μm or more and 5 μm or less.

In the photodetector according to this embodiment, the number of carriers formed by the secondary photons is suppressed by setting the thickness of the n-type semiconductor layer 40 to be between 3 μm and 5 μm. In addition, as the concentration of the n-type semiconductor layer 40 becomes high, the carriers formed by the secondary photons can be more easily removed. Therefore, even if a large voltage is applied, it is possible to provide a photodetector with less noise.

### Modified Example

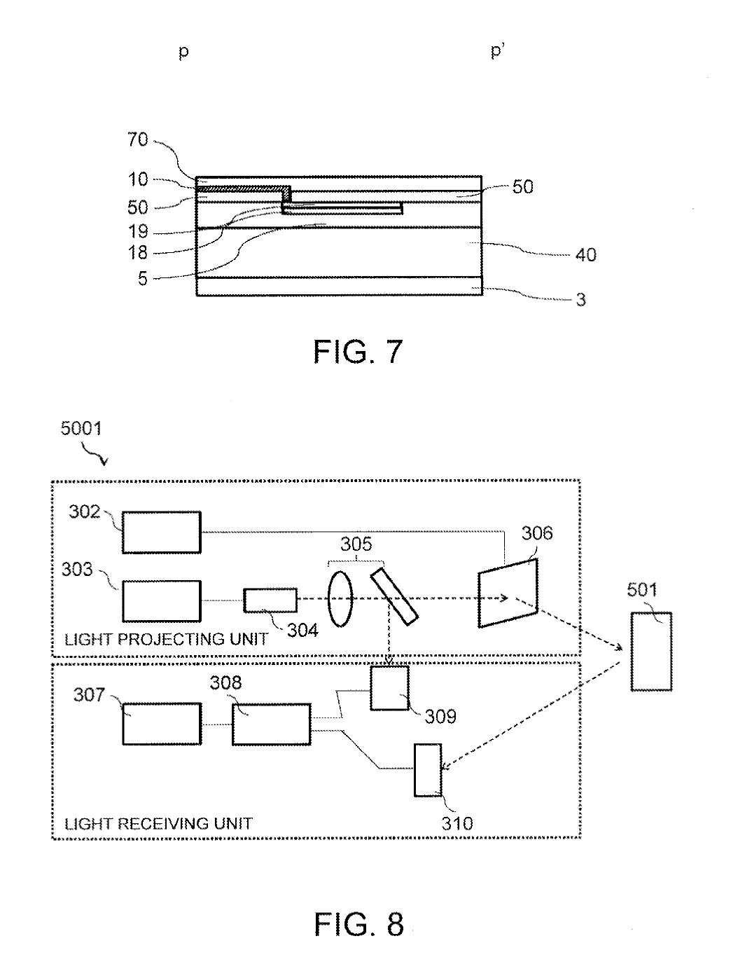

FIG. 7 is a diagram illustrating a modified example of the photodetector according to the first embodiment.

Differences from the photodetector according to the first embodiment will be described. The modified example of the photodetector according to the first embodiment is different in that the semiconductor type of the first semiconductor layer 40 is p-type and the semiconductor type of the second semiconductor layer 5 is p-type. In addition, on the upper surface side of the second semiconductor layer 5, the p-type semiconductor layer 18 and the n-type semiconductor layer 19 form a pn junction. Furthermore, the voltage between the first electrode 3 and the second electrode 10 is applied in a direction opposite to the direction applied to the photodetector according to the first embodiment. When carriers reach the vicinity of the pn junction, the carriers cause avalanche amplification.

In the modified example of the photodetector according to the first embodiment, similarly to the photodetector according to the first embodiment, the number of carriers formed by secondary photons is suppressed.

### Second Embodiment

FIG. 8 illustrates a laser imaging detection and ranging (LIDAR) apparatus 5001 according to the second embodiment.

This embodiment can be applied to a long-distance subject detection system (LIDAR) configured with a line light source, a lens, and the like. The LIDAR apparatus 5001 includes a light projecting unit T which projects laser light to the object 501, a light receiving unit R (also referred to as a photodetection system) which receives the laser light reflected from the object 501 and measures a time when the laser light reciprocates to return from the object 501 and converts the time to a distance.

In the light projecting unit T, the laser light oscillator 304 oscillates laser light. A driving circuit 303 drives the laser light oscillator 304. The optical system 305 extracts a portion of the laser light as a reference light and irradiates the object 501 with the other laser light through the mirror 306. The mirror controller 302 controls the mirror 306 to project the laser light onto the object 501. Herein, projecting denotes irradiating with light.

In the light receiving unit R, the reference-light photodetector 309 detects the reference light emitted by the optical system 305. The photodetector 310 receives reflected light from the object 501. The distance measurement circuit 308 measures the distance to the object 501 based on the reference light detected by the reference-light photodetector 309 and the reflected light detected by the photodetector 310. The image recognition system 307 recognizes the object 501 based on a result measured by the distance measurement circuit 308.

The LIDAR apparatus 5001 employs a time-of-flight (TOF) distance measurement method which measures a time when the laser light reciprocates to return from the object 501 and reduces the time into a distance. The LIDAR apparatus 5001 is applied to an in-vehicle drive-assist system, remote sensing, or the like. When the photodetectors according to this embodiment are used as the photodetector 310, the photodetector exhibits good sensitivity particularly in a near infrared region. Therefore, the LIDAR apparatus 5001 can be applied to a light source to a wavelength band invisible to a person. For example, the LIDAR apparatus 5001 can be used for detecting obstacles for vehicles.

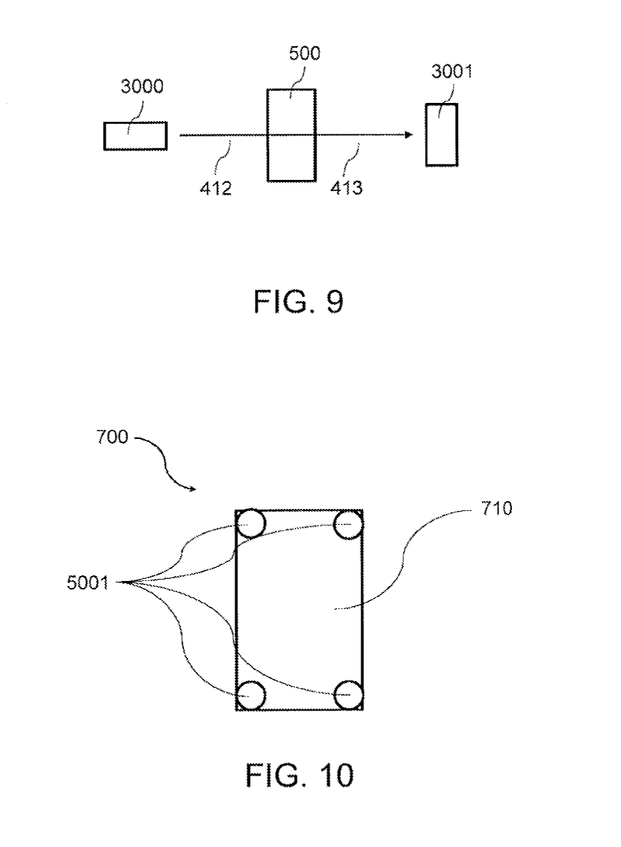

FIG. 9 is a diagram illustrating the detection of a detection object of the LIDAR apparatus.

The light source 3000 emits light 412 to an object 500 to be detected. The photodetector 3001 detects the light 413 transmitted through, reflected by, or diffused by the object 500.

For example, the photodetector 3001 realizes highly sensitive detection by using the above-described photodetectors according to this embodiment.

It is preferable that a plurality of sets of the photodetector 3001 and the light source 3000 are provided and the arrangement relationship thereof is set in software (circuits can be used as substitutes) in advance. It is preferable that, as the arrangement relationship of the sets of the photodetector 3001 and the light source 3000, the sets are provided, for example, at equal intervals. Accordingly, by complementing the output signals of the respective photodetectors 310, an accurate three-dimensional image can be generated.

FIG. 10 is a schematic top view of a vehicle equipped with the LIDAR apparatus according to this embodiment.

A vehicle 700 according to this embodiment includes the LIDAR apparatuses 5001 at the four corners of a vehicle body 710.

Since the LIDAR apparatuses are provided at the four corners of the vehicle body, the vehicle according to this embodiment can detect the environment in all directions of the vehicle by the LIDAR apparatuses.

While several embodiments of the invention have been described above, the above-described embodiments have been presented by way of examples only, and the embodiments are not intended to limit the scope of the invention. The embodiments described herein may be embodied in a variety of other forms; furthermore, various omissions, substitutions, and changes in the form of the embodiments described herein may be made within the scope without departing from the spirit of the invention. The embodiments and modifications thereof are included in the scope and spirit of the invention and fall within the scope of the invention described in the claims and the equivalents thereof.

What is claimed is:

1. A photodetection element comprising:
a first semiconductor layer; and
a second semiconductor layer stacked on the first layer and converting light into electric charges;
wherein the first semiconductor layer has thickness of 5 μm or less.

2. The photodetection element of claim 1,
wherein the first semiconductor layer formed by doping with impurities at a concentration of 1×10¹⁶/cm³ or more.

3. The photodetection element of claim 2,
wherein the first semiconductor layer has a thickness of 3 μm or more and 5 μm or less.

4. The photodetection element of claim 3,
wherein the second semiconductor layer has a thickness of 2 μm or more and 4 μm or less.

5. The photodetection element of claim 4,
wherein the photodetection element is an avalanche photodiode which operates in the Geiger mode.

6. A photodetector comprising:
a photodetection element including a first semiconductor layer and a second semiconductor layer stacked on the first layer and converting light into electric charges, wherein the first semiconductor layer has a thickness of 5 μm or less.
wherein the photodetection element is arranged in an array.

7. A photodetection system comprising:
a photodetector including a photodetection element having a first semiconductor layer and a second semiconductor layer stacked on the first layer and converting light into electric charges, wherein the first semiconductor layer has a thickness of 5 μm or less, wherein the photodetection element is arranged in an array; and
a distance measurement circuit calculating a time-of-flight of light from an output signal of the photodetector

8. A LIDAR apparatus comprising:
a light source emitting light to an object; and
a photodetection system including photodetector including a photodetection element having a first semiconductor layer and a second semiconductor layer stacked on the first layer and converting light into electric charges, wherein the first semiconductor layer has a thickness of 5 μm or less and wherein the photodetection elements are arranged in an array;
wherein the photodetection system detects incident light reflected by the object.

9. The LIDAR apparatus according to claim 8, further comprising;
a generation element for generating a three-dimensional image on the basis of an arrangement relationship between the light source and the photodetector.
